(19) United States
(12) Patent Application Publication
(10) Pub. No.: US 2013/0058066 A1
(43) Pub. Date: Mar. 7, 2013

(54) ELECTRONIC DEVICE

(71) Applicant: Yukiko Yokoyama, Suntou-gun (JP)

(72) Inventor: Yukiko Yokoyama, Suntou-gun (JP)

(73) Assignee: TOSHIBA TEC KABUSHIKI KAISHA, Tokyo (JP)

(21) Appl. No.: 13/600,443

(22) Filed: Aug. 31, 2012

(30) Foreign Application Priority Data
Sep. 6, 2011 (JP) 2011-193690

(51) Int. Cl. H05K 5/00

(52) U.S. Cl. 361/807

(57) ABSTRACT

An electronic device comprises two printer sections which are arranged in parallel and include a paper storage section and print onto a recording paper hold in the paper storage section and two display sections which are arranged at the position where the transfer of the recording paper into and from the two printer sections is not impeded when the recording paper is changed, and is located at a position between the two printer sections, wherein the widths of the two display sections are each not greater than the width of the two printers arranged in parallel.

### CROSS-REFERENCE TO RELATED APPLICATION

This application is based upon and claims the benefit of priority from Japanese Patent Application No. 2011-193690, filed Sep. 6, 2011, the entire contents of which are incorporated herein by reference.

### FIELD

Embodiments described herein relate to an electronic device.

### BACKGROUND

Previously, in a supermarket or a retail store, in order to conduct merchandise sale data processing, an electronic device such as a POS (Point of Sales) terminal with a screen for operator and a screen for customer is used.

The previous POS terminal is installed in a manner that components such as a keyboard, a display section for salesclerk, a display section for customer, a receipt printer, and a journal printer etc. are arranged in a planar direction.

### BRIEF DESCRIPTION OF THE DRAWINGS

FIG. 1 is a front perspective view showing a POS terminal according to the present embodiment.

FIG. 2 is a back perspective view of the above-described POS terminal.

FIG. 3 is a diagram showing another configuration of a receipt printer and a journal printer.

FIG. 4 is a diagram showing a further other configuration of the receipt printer and the journal printer.

FIG. 5 is diagram showing a condition in which the receipt printer and the journal printer slide in a horizontal direction.

FIG. 6 is a diagram showing a further other configuration of the receipt printer and the journal printer.

### DETAILED DESCRIPTION

According to one embodiment, an electronic device comprises two printer sections which are arranged in parallel and include a paper storage section and print onto a recording paper hold in the paper storage section and two display sections which are arranged at the position where the transfer of the recording paper into and from the two printer sections is not impeded when the recording paper is changed, and is located at a position between the two printer sections, wherein the widths of the two display sections are each not greater than the width of the two printers arranged in parallel.

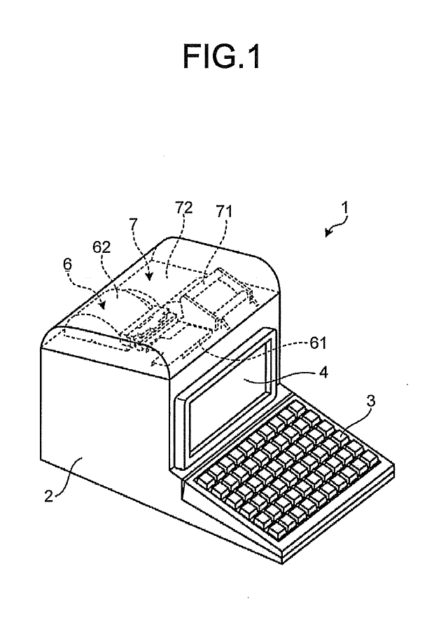

Hereinafter, the POS terminal as an electronic device according to the present embodiment is illustrated with reference to FIGS. 1-6.

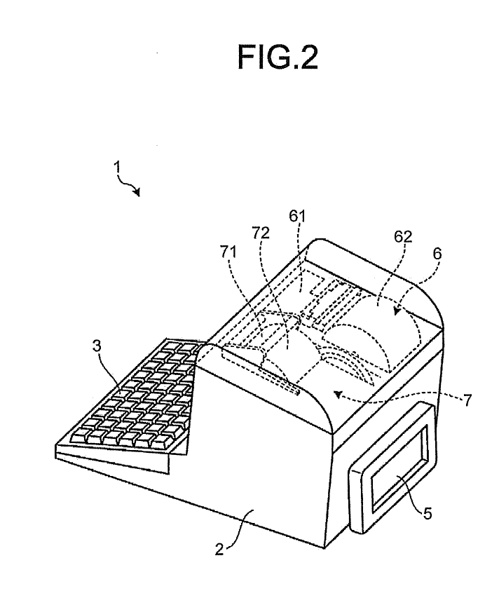

FIGS. 1 and 2 are the front perspective view and the back perspective view showing the schematic external configuration of the POS terminal according to the present embodiment.

The POS terminal 1 is an electronic device which is installed at a checkout area of a shop and conducts registration processing and account processing for commodity purchased by a customer. As shown in FIGS. 1 and 2, the POS terminal 1 comprises a main body 2, a keyboard 3, a display section for salesclerk 4, a display section for customer 5, a receipt printer 6, and a journal printer 7.

Within the interior of the main body 2, an information processing section (not shown) conducting various information processing or a storage section (not shown) storing various information etc. are arranged.

At one end of the upper side of the main body 2, a keyboard 3 with various function keys such as numerical keypad for a salesclerk conducting various operations is arranged.

At a upper part of the main body 2 and at a position adjacent to the keyboard 3, a receipt printer 6 and a journal printer 7 with nearly same approximately rectangular shape, in a state of respective longitudinal direction facing the keyboard 3 side (state of “transverse placement”), are closely arranged in a direction perpendicular to the longitudinal direction.

The receipt printer 6 prints the purchased commodity items or their total amount etc. onto a continuous-feed paper hold in a paper storage section (not shown) arranged in the interior and then sends out the paper as a receipt. The receipt is ejected from a receipt outlet 61 arranged at a upper side of the receipt printer 6. In a usual usage state (a state in which the receipt can be printed), the paper storage section of the receipt printer 6 is closed by an openable and closable cover 62.

The journal printer 7 prints the data such as one day sales result etc. stored in a storage section arranged in the interior of the main body 2 of the POS terminal 1 onto the continuous-feed paper hold in a paper storage section (not shown) arranged in the interior and then sends out the paper as a journal. The journal is ejected form a journal outlet 71 arranged at the upper side of the journal printer 7. In a usual usage state (a state in which the journal can be printed), the paper storage section of the journal printer 7 is closed by an openable and closable cover 72.

At a position adjacent to the end of the receipt printer 6 and the journal printer 7 arranged in parallel at the keyboard 3 side, the display section for salesclerk 4 displaying various information such as processing details etc. to the salesclerk is arranged in a manner that it uprises from the main body section in an approximately vertical direction.

At a position adjacent to a end of the side opposite to the side of the receipt printer 6 and the journal printer 7 arranged in parallel at the keyboard 3 side, the display section for customer 5 displaying various information such as billing amount to the customer, is arranged in a manner that it uprises from the main body 2 in an approximately vertical direction.

Respective width of the display section for salesclerk 4 and the display section for customer 5 is smaller than the combined width of the receipt printer 6 and the journal printer 7 arranged in parallel. Therefore, it is unnecessary to increase the size of the main body 2 in a planar direction in order to arrange the display section for salesclerk 4 and the display section for customer 5, thus the POS terminal 1 can be downsized in a planar direction.

According to above-described configuration, even if each component are closely configured, the display section for salesclerk 4 and the display section for customer 5 do not enter the motion range of a cover 62 of the receipt printer 6 and a cover 72 of the journal printer 7 when the covers are opened and closed. Therefore, the motion range of the cover 62 of the receipt printer 6 and the cover 72 of the journal printer 7, that is, a space required for the transfer of the continuous-feed paper into and from the paper storage sections of the receipt printer 6 and the journal printer 7 when the continuous-feed paper is changed or a space required for maintenance work to the receipt printer 6 and the journal printer 7 can be insured, and each component can be closely arranged in the planar direction. As s result, a POS terminal with excellent space-saving property in the planar direction and the area required for installation being small is obtained.

The above-described embodiment is presented as an example, and it is not intended to limit the scope of the invention. The novel embodiment may be implemented in other various forms, and various omissions, replacements, and modifications can be done without departing from the gist of the invention. The embodiment or its variation is included in the scope or the gist of the invention and included in the invention recited in the claim or its equivalent.

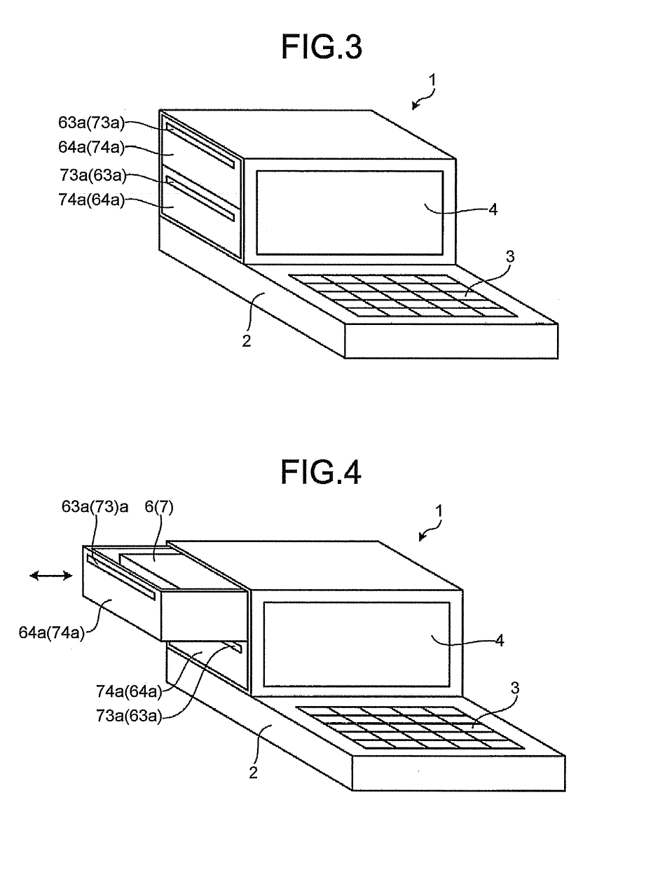

For example, as shown in FIGS. 3 and 4, the receipt printer 6 and the journal printer 7 may also be hold in a rectangular storage sections 64a, 74a in which the receipt printer 6 and the journal printer 7 can slide in a horizontal direction via a slide mechanism (not shown), and which is configured that the longitudinal direction faces the horizontal direction and the receipt printer 6 and the journal printer 7 overlap in the vertical direction.

If being in a state of the upper sides of the storage sections 64a, 74a are opened and the storage sections 64a, 74a slide in a horizontal direction and the receipt printer 6 or the journal printer 7 hold in the interior are exposed to the exterior, when the continuous-feed paper is changed the covers 62, 72 of the receipt printer 6 or the journal printer 7 are opened and the operation of transfer of the continuous-feed paper is conducted and the maintenance work of the receipt printer 6 or the journal printer 7 is conducted. FIG. 4 shows a state in which the section at the upper stage of the storage sections 64a, 74a slides in the horizontal direction.

Within the storage sections 64a, 74a, a receipt ejecting section 63a and a journal ejecting section 73a used for sending the receipt and the journal to exterior from the receipt printer 6 and the journal printer 7 which are hold in the interior. The receipt ejecting section 63a and the journal ejecting section 73a are arranged at one lateral side of the POS terminal 1 (in the embodiment, the left side viewed from the display section for salesclerk 4 side).

Then, being adjacent to the side in the direction perpendicular to the longitudinal direction of the storage sections 64a, 74a, the display section for salesclerk 4 and the display section for customer 5 are arranged opposite to each other. In this case, the widths of the display section for salesclerk 4 and the display section for customer 5 are each smaller than the length of the storage sections 64a, 74a in a longitudinal direction.

By forming such configuration, the space required for the transfer of the continuous-feed paper into and from the paper storage section of the receipt printer 6 and the journal printer 7 when the continuous-feed paper are replaced or the maintenance work to the receipt printer 6 and the journal printer 7 can be ensured, and the components can be closely arranged in the planar direction. In addition, the space for arranging one of the storage sections 64a, 74a in the planar direction may be insured. Therefore, a POS terminal having more excellent space-saving property in the planar direction can be formed.

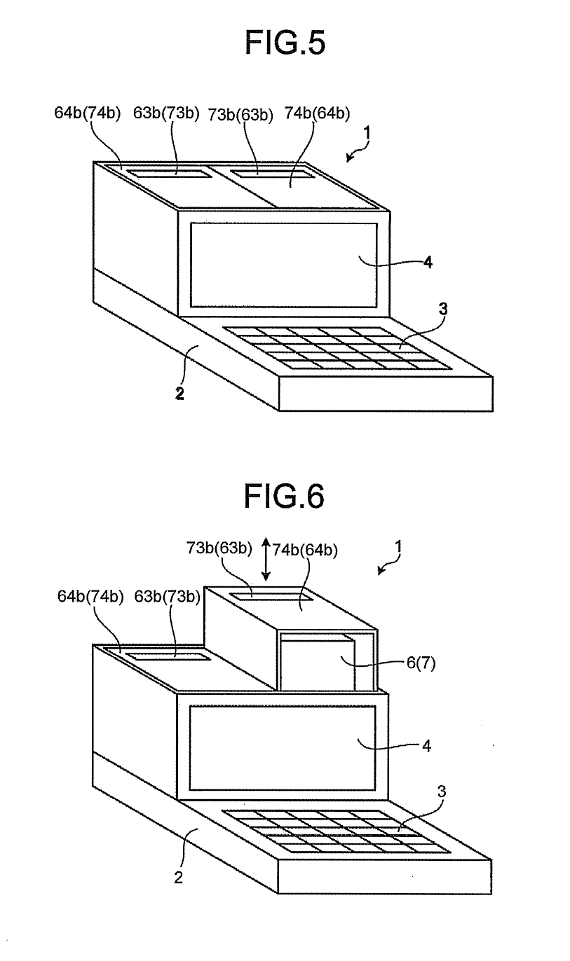

As shown in FIGS. 5 and 6, the receipt printer 6 and the journal printer 7 can slide in the vertical direction by a slide mechanism (not shown), and the receipt printer 6 and the journal printer 7 may be hold in the rectangular storage sections 64b, 74b closely arranged in parallel in the planar direction in a state of the longitudinal direction facing to the vertical direction (a state of “vertical placement”).

If being in a state in which the front side of the storage sections 64b, 74b is opened and the storage sections 64b, 74b slides in the vertical direction and the receipt printer 6 or the journal printer 7 hold in the interior is exposed to the exterior, then the transfer of the continuous-feed paper into and from the receipt printer 6 or the journal printer 7 when the continuous-feed paper is changed or the maintenance work to the receipt printer 6 or the journal printer 7 is conducted. FIG. 6 shows a state in which one section of the storage sections 64b, 74b being at the right side viewed from the display section for salesclerk 4 side slides in the vertical direction.

Within the storage sections 64b, 74b, a receipt ejecting section 63b and a journal ejecting section 73b used for ejecting the receipt and the journal to the exterior form the receipt printer 6 and journal printer 7 hold in the interior are arranged. The receipt ejecting section 63b and the journal ejecting section 73b are arranged at the superior surface of the storage sections 64b, 74b.

Then, being adjacent to the lateral side which is in the direction perpendicular to the longitudinal direction of the storage sections 64b, 74b, the display section for salesclerk 4 is arranged opposite to the display section for customer 5. In this case, the widths of the display section for salesclerk 4 and the display section for customer 5 are each smaller than the combined width of the storage sections 64b, 74b arranged in parallel.

By forming such configuration, the space required for the transfer of the continuous-feed paper into and from the paper storage sections of the receipt printer 6 and the journal printer 7 when the continuous-feed paper is changed or the space required for the maintenance work to the receipt printer 6 and the journal printer 7 is ensured, and the components can be closely arranged in the planar direction. In addition, because the approximately rectangular storage sections 64a, 74a are vertically placed, compared with the case in which the storage sections 64a, 74a are transversely placed, the space-saving property in the planar direction is improved. Therefore, a POS terminal with more excellent space-saving property in the planar direction is obtained.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electronic device, comprising:
two printer sections which are arranged in parallel and include a paper storage section and print onto a recording paper hold in the paper storage section; and
two display sections which are arranged at the position where the transfer of the recording paper into and from the two printer sections is not impeded when the recording paper is changed, and is located at a position between the two printer sections, wherein
the widths of the two display sections are each not greater than the width of the two printers arranged in parallel.

2. The electronic device according to claim 1, wherein
the shapes of the two printer sections are approximately rectangular, and the two printer sections are transversely placed and arranged in parallel in a planar direction.

3. The electronic device according to claim 1, wherein
the shapes of the two printer sections are approximately rectangular, and the two printer sections are transversely placed and overlap in a vertical direction.

4. The electronic device according to claim 1, wherein
the shapes of the two printer section are approximately rectangular, and the two printer sections are vertically placed and are arranged in parallel in the planar direction.

5. The electronic device according to claim 3, wherein
the two printer sections are each hold in the storage section with one side being opened.

6. The electronic device according to claim 4, wherein the two printer sections are each hold in the storage section with one side being opened.

7. The electronic device according to claim 5, wherein
the storage sections are arranged in a manner of being able to slide.

8. The electronic device according to claim 6, wherein
the storage sections are arranged in a manner of being able to slide.
